(19) United States
(12) Patent Application Publication
(10) Pub. No.: US 2005/0284361 A1
(43) Pub. Date: Dec. 29, 2005

(54) Method and apparatus for applying a layer of a second material to a layer of a nanocrystalline first material

(76) Inventors: Rudolf Peter Muis, Sijbekarspel (NL); Brian Coolidge O'Regan, Amsterdam (NL)

Correspondence Address: Michael D Bednarek;Shaw Pittman, 1650 Tysons Boulevard, McLean, VA, 22102, US

(21) Appl. No.: 10/514,424

(22) PCT Filed: May 15, 2003
(86) PCT No.: PCT/NL03/00357

§ 371 Date: May 26, 2005

(30) Foreign Application Priority Data
May 29, 2002 (NL) 1020701

(51) Int. Cl. C30B 11/00; H01G 9/20; H01L 21/20; H01L 21/36

(52) U.S. Cl. 117/206; 438/497

(57) ABSTRACT

Method for applying a layer of a second material to a layer of a nonocrystalline first material, comprising the steps of (i) providing a layer of a nonocrystalline first material on a horizontal substrate, (ii) providing a liquid containing the second material, (iii) providing a tubular dispensing means to be disposed horizontally and provided with lateral outlet openings, (iv) disposing the dispensing means above the layer of nonocrystalline material, and (v) displacing the dispensing means and the layer of nanocrystalline material relative to each other in lateral horizontal direction of the dispensing means, while simultaneously supplying the liquid with the second material to the dispensing means, and apparatus for performing this method.

The invention relates to a method for applying a layer of a second material to a layer of a nanocrystalline first material.

Such a method is known from European patent application EP-A-1107333 for a photoelectric conversion device, where the manufacture of a work electrode for a photovoltaic element is described.

The work electrode described in this patent application comprises a conductive layer which is applied to a glass substrate and to which are successively applied a first layer of a nanocrystalline titanium dioxide, provided with a dye sensitizer and a second layer of a thiocyanate acting as a charge transfer medium. The second layer is applied in known manner by using an Eppendorf to drip a determined amount of a solution of the thiocyanate in acetonitrile onto the substrate with the first layer, wherein the substrate rests on a heating plate in order to evaporate the solvent.

The known method has the drawback that it is particularly difficult to apply a second layer that is homogenous onto a first layer of a nanocrystalline material in reproducible manner. The thickness of the charge transfer layers described in the cited patent application amounted to between 15 μm and 30 μm.

Another drawback is the long period of time involved in applying a layer of a sufficient width for a photovoltaic element.

A further drawback of the known method is that it is difficult to scale up, i.e. it cannot be readily applied for the manufacture of photovoltaic elements on industrial scale.

It is an object of the invention to provide a method in accordance with which it is possible in reproducible manner to apply a second layer that is homogenous onto a first layer of a nanocrystalline material.

It is a further object to provide a method in accordance with which a layer of a sufficient width for a photovoltaic element can be applied in a short period of time.

It is yet another object to provide a method which can be readily applied for the manufacture of photovoltaic elements on industrial scale.

These goals are achieved with a method of the type stated in the preamble, which according to the invention comprises the steps of (i) providing a layer of a nanocrystalline first material on a horizontal substrate, (ii) providing a liquid containing the second material, (iii) providing a tubular dispensing means to be disposed horizontally and provided with lateral outlet openings, (iv) disposing the dispensing means above the layer of nanocrystalline material, and (v) displacing the dispensing means and the layer of nanocrystalline material relative to each other in lateral horizontal direction of the dispensing means, while simultaneously supplying the liquid with the second material to the dispensing means.

During performing of the fifth step (v) liquid flows from the dispensing means onto the layer of the nanocrystalline material, where the liquid firstly penetrates into the pores of this material and subsequently forms a layer on the material.

The liquid containing the second material to be provided in the second step (ii) is preferably a solution with this second material, from which the second material can be precipitated by evaporation of the solvent, but can also be the second material in liquid phase which solidifies after being applied to the layer of nanocrystalline material.

The invention further relates to an apparatus for performing the above described method, which apparatus according to the invention comprises at least one tubular dispensing means to be disposed horizontally and provided with lateral outlet openings, a liquid container and conduit means for carrying liquid from the liquid container to the at least one dispensing means.

One embodiment of an apparatus according to the invention is provided with displacing means for displacing the dispensing means and the layer of nanocrystalline material relative to each other in lateral horizontal direction of the dispensing means, which displacing means comprise for instance a carrier displaceable in horizontal direction relative to the dispensing means for carrying and displacing a layer of nanocrystalline material in lateral direction relative to the dispensing means.

In an advantageous embodiment the displacing means comprise an XY table.

In an embodiment which is particularly suitable for use in applying a layer of a second material that is provided in dissolved state in a solvent, the apparatus according to the invention is provided with heating means to heat a layer of a nanocrystalline material during performing of the method.

In one embodiment the tubular dispensing means is connected at a first outer end to a first liquid supply line and is closed at a second outer end. In this embodiment the liquid to be dispensed is supplied via the first outer end of the tubular dispensing means and is deposited via the outlet openings onto the layer of nanocrystalline material.

In a subsequent embodiment the tubular dispensing means is connected at a first outer end to a first liquid supply line, and is connected at a second outer end to a liquid circulation line or a second liquid supply line.

This latter embodiment is particularly suitable for use in applying a relatively wide layer. The tubular dispensing means herein forms part of a U-shaped structure, wherein the dispensing means is suspended at a first outer end from a first liquid supply line, and at a second outer end is suspended from a liquid circulation line or from a second liquid supply line.

It has been found that an exceptionally homogenous layer is applied with an apparatus according to the invention wherein the lateral outlet openings are provided in the top side of a horizontally disposed tubular dispensing means.

The tubular dispensing means preferably has a circular outer periphery in vertical cross-section.

A tubular dispensing means with a circular outer periphery has the advantage that the tube required for this purpose is commercially available in the desired sizes, so that the dispensing means can be manufactured in simple manner and at low cost.

The present invention will be elucidated hereinbelow on the basis of an embodiment of an apparatus and with reference to the drawing.

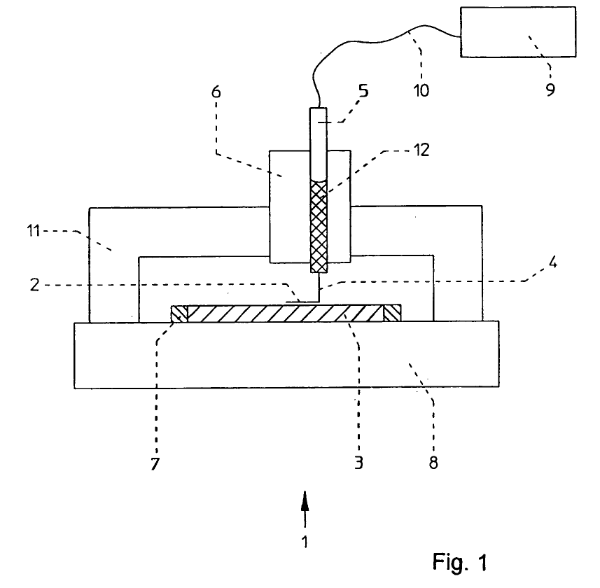

FIG. 1 shows a front view of a simplified view of an embodiment of an apparatus 1 for applying a second layer of a soluble material to a first layer of a nanocrystalline material. The figure shows an L-shaped injection needle, a part 2 of which is arranged horizontally above a horizontally placed copper substrate table 3, and a vertical part 4 of which is connected to a supply container 5 for a solution 12 of a material to be applied. The injection needle 2, 4 has an internal diameter of 0.4 mm. The horizontal part 2 thereof forms the dispensing tube which is closed at its free outer end, and which is provided on its upper side with a number of outlet openings with a diameter of 0.1 mm (not shown). Supply container 5 and L-shaped injection needle 2, 4 are mounted on a height adjusting device 6 for adjusting the distance between the dispensing tube 2 and a substrate with nanocrystalline layer laid on substrate table 3 (not shown). Substrate table 3 is displaceable in lateral horizontal direction of dispensing tube 2 (perpendicularly of the plane of the drawing) between longitudinal guides 7 over a heating plate 8. The figure further shows another liquid metering pump 9 which is connected with a flexible conduit 10 to supply container 5 and a fixed yoke 11 for suspending the height adjusting device 6. Not shown is a switch box with measuring and control electronics for height adjusting device 6, the temperature adjustment of heating plate 8, the displacement of substrate table 3 and metering pump 9.

It is noted that the described embodiment serves to elucidate the invention, and not to limit the scope of protection of the patent applied for. It is for instance possible to embody the tube part 2 as a horizontal part of a U-shaped injection needle. The width of the homogenous layer laid on the layer of nanocrystalline material is after all determined by the length of the tube part 2, which length is inherently limited, at a determined number of outlet openings of a determined diameter, by the internal diameter of tube part 2. The use of a U-shaped injection needle achieves that within these limitations this length is doubled, wherein liquid is fed via both outer ends to the horizontal part. It is further possible to increase the width of the homogenous layer by simultaneously displacing more than one tubular dispensing means above a substrate. It is also possible to increase the width of the homogenous layer by replacing the substrate holder (the copper table 3), which is displaceable in longitudinal direction, with an XY table, i.e. a substrate holder displaceable in longitudinal direction and width. It is further possible to replace the copper table 3 which rests on a heating plate 8 with a substrate holder provided with a eating element.

1. Method for applying a layer of a second material to a layer of a nanocrystalline first material, comprising the steps of
(i) providing a layer of a nanocrystalline first material on a horizontal substrate (3),
(ii) providing a liquid (12) containing the second material,
(iii) providing a tubular dispensing means (2) to be disposed horizontally and provided with lateral outlet 10 openings,
(iv) disposing the dispensing means (2) above the layer of nanocrystalline material, and
(v) displacing the dispensing means (2) and the layer of nanocrystalline material relative to each other in lateral horizontal direction of the dispensing means (2), while simultaneously supplying the liquid (12) with the second material to the dispensing means (2).

2. Apparatus (1) for applying a layer of a second material to a layer of a nanocrystalline first material in accordance with a method as claimed in claim 1, comprising a tubular dispensing means (2) to be disposed horizontally and provided with lateral outlet openings, a liquid container (5) and conduit means (4, 9, 10) for carrying liquid (12) from the liquid container (5) to the dispensing means (2).

3. Apparatus (1) as claimed in claim 2, characterized in that it is provided with displacing means (3, 7) for displacing the dispensing means (2) and the layer of nanocrystalline material relative to each other in lateral horizontal direction of the dispensing means (2).

4. Apparatus (1) as claimed in claim 3, characterized in that the displacing means comprise a carrier (3) displaceable in horizontal direction relative to the dispensing means (2) for carrying arid displacing a layer of nanocrystalline material in lateral direction relative to the dispensing means (2).

5. Apparatus (1) as claimed in claim 3, characterized in that the displacing means comprise an XY table.

6. Apparatus (1) as claimed in, claim 2 characterized in that it is provided with heating means (8) for heating a layer of a nanocrystalline material during performing of the method.

7. Apparatus (1) as claimed in, claim 2 characterized in that the tubular dispensing means (2) is connected at a first outer end to a first liquid supply line (4) and is closed at a second outer end.

8. Apparatus (1) as claimed in, claim 2 characterized in that the tubular dispensing means is connected at a first outer end to a first liquid supply line, and is connected at a second outer end to a liquid circulation line or a second liquid supply line.

9. Apparatus (1) as claimed in, claim 2 characterized in that the lateral outlet openings are provided in the top side of a horizontally disposed tubular dispensing means (2).

10. Apparatus (1) as claimed claim 2, characterized in that the tubular dispensing means (2) has a circular outer periphery in vertical cross-section.

11. Apparatus (1) as claimed in claim 2, characterized in that the conduit means comprise a liquid metering pump (9).
